(19) United States
(12) Patent Application Publication
(10) Pub. No.: US 2019/0229255 A1
(43) Pub. Date: Jul. 25, 2019

(54) PIEZOELECTRIC ELEMENT AND METHOD OF MANUFACTURING THE SAME

(71) Applicants: NTN CORPORATION, Osaka (JP); Nagoya Institute of Technology, Aichi (JP)

(72) Inventors: Ken YASUDA, Mie (JP); Yasutake HAYAKAWA, Mie (JP); Kouya OOHIRA, Mie (JP); Kenichi KAKIMOTO, Aichi (JP)

(21) Appl. No.: 16/341,881

(22) PCT Filed: Oct. 12, 2017
(86) PCT No.: PCT/JP2017/037030

§ 371 Date: Apr. 12, 2019

(30) Foreign Application Priority Data
Oct. 12, 2016 (JP) 2016-200863
Oct. 12, 2017 (JP) 2017-198502

(51) Int. Cl. H01L 41/08; B32B 5/02; B32B 27/12; B32B 27/30; H02N 2/18; H02N 2/00; H01L 41/083; H01L 41/18; H01L 41/113; H01L 41/277; H01L 41/37; H01L 41/257

(52) U.S. Cl. CPC H01L 41/082; B32B 5/022; B32B 27/12; B32B 27/306; B32B 27/304; H02N 2/186; B29C 43/203; H01L 41/083; H01L 41/183; H01L 41/113; H01L 41/277; H01L 41/37; H01L 41/257; H02N 2/22

(57) ABSTRACT

Provided are a piezoelectric device capable of exhibiting high power-generation performance without impairing flexibility and a method of manufacturing the piezoelectric device. The piezoelectric device includes a multilayer structure 1 in which a polymer nonwoven fabric 3 holding or containing piezoelectric ceramic particles 4 and a polymer resin sheet 2 containing piezoelectric ceramic particles are stacked such that at least one layer of the polymer nonwoven fabric is included. This multilayer structure can provide an electric power output equal to or larger than the electric power output produced by a multilayer structure in which a layer of the polymer resin sheet is stacked on each of two main surface sides of a layer of the polymer nonwoven fabric.

### TECHNICAL FIELD

The present invention relates to a piezoelectric device and a method of manufacturing the same, and more particularly to a piezoelectric device suitable for vibration energy harvesting using ambient vibration.

### BACKGROUND ART

Energy harvesting, which is a process of capturing and converting ambient energy such as vibration, solar light, room light, and radio waves into electricity, has drawn attention and increasingly been applied to autonomous power supplies of electronic devices and the like. In energy harvesting, power generation using vibration is called vibration energy harvesting and there are systems such as piezoelectric, magnetic induction, and electrostatic induction systems.

The piezoelectric system using a piezoelectric device as a power generating element utilizes the piezoelectric properties of the material and therefore is advantageous in its simple structure compared with electromagnetic induction and electrostatic induction systems. The characteristics required for piezoelectric devices include high power-generation performance and shock resistance.

Materials forming piezoelectric devices are mainly classified into inorganic piezoelectric materials and organic piezoelectric materials. As an inorganic piezoelectric material, ceramics having the perovskite crystal structure, such as lead zirconate titanate (PZT), are widely used. Examples of the organic piezoelectric material include polyvinylidene fluoride (hereinafter referred to as PVDF), a vinylidene fluoride-trifluoroethylene copolymer, and polylactic acid. The inorganic piezoelectric materials are superior to the organic piezoelectric materials in power-generation performance but inferior in flexibility and shock resistance.

An attempt is made to combine an inorganic piezoelectric material with an organic piezoelectric material to fabricate a piezoelectric device having high power-generation performance as well as flexibility and shock resistance. For example, Patent Document 1 proposes a composite piezoelectric device formed by stacking piezoelectric material layers containing a resin and piezoelectric particles, in which a second piezoelectric material layer having a piezoelectric particles density lower than a first piezoelectric material layer is disposed between two first piezoelectric material layers. The lower density of piezoelectric particles in the second piezoelectric material layer improves the flexural strength of the composite piezoelectric device. Patent Document 2 discloses a piezoelectric sheet that includes nonwoven fabrics or woven fabrics formed with fibers including an organic polymer and includes an inorganic filler.

Non-Patent Document 1 proposes a piezoelectric device in which a sheet layer composed of a polyvinyl alcohol (hereinafter referred to as PVA) resin composition containing a sodium potassium niobate solution (hereinafter referred to as NKN) particles and a nonwoven fabric layer including NKN particles held in a nonwoven fabric composed of PVDF fiber are alternately stacked and integrated. This structure has a porous nonwoven fabric layer and may be more flexible than the structure of Patent Document 1.

### PRIOR ART DOCUMENTS

### Patent Documents

Patent Document 1: Japanese Patent Application Laid-Open No. 2015-50432
Patent Document 2: WO2015/005420

### Non Patent Document

Non Patent Document 1: M. Kato, K. Kakimoto, Materials Letters, 156, 183-186 (2015)

### SUMMARY OF THE INVENTION

### Problems to be Solved by the Invention

However, in Non-Patent Document 1, both surfaces of the piezoelectric device are sheet layers composed of a PVA resin composition containing NKN particles. In order to further improve the power-generation performance, the PVA resin composition needs to be highly filled with NKN particles to increase the surface charge density of the sheet layer surface so that electric charge is easily extracted. There is no discussion as to how the power-generation performance is affected by the thickness of the sheet layer, the thickness of the nonwoven fabric layer, and the number of layers of sheet layers and nonwoven fabric layers. The power-generation performance of the multilayer structure including sheet layers and nonwoven fabric layers is not discussed in Patent Document 2, either.

The present invention is made in order to address such problems and aims to provide a piezoelectric device that can exhibit high power-generation performance without impairing flexibility and a method of manufacturing the same.

### Means for Solving the Problem

A piezoelectric device according to the present invention includes a multilayer structure in which a polymer nonwoven fabric holding or containing piezoelectric ceramic particles and a polymer resin sheet containing piezoelectric ceramic particles are stacked such that at least one layer of the polymer nonwoven fabric is included. The multilayer structure is a multilayer structure that is able to provide an electric power output equal to or larger than an electric power output produced by a multilayer structure in which a layer of the polymer resin sheet is stacked on each of two main surface sides of a layer of the polymer nonwoven fabric.

The polymer resin sheet is a sheet with a thickness per layer of 10 μm to 100 μm in which 50% by volume to 80% by volume of piezoelectric ceramic particles are contained. The polymer nonwoven fabric is a nonwoven fabric with a thickness per layer of 10 μm to 300 μm in which an average diameter of fibers forming the polymer nonwoven fabric is 0.05 μm to 5 μm and 30% by volume to 60% by volume of piezoelectric ceramic particles are held or contained.

In the multilayer structure in the present invention, a plurality of the polymer nonwoven fabrics are stacked or the polymer nonwoven fabric and the polymer resin sheet are alternately stacked. In particular, each of two main surface sides of the multilayer structure is the polymer resin sheet.

The present invention provides a method of manufacturing a piezoelectric device. The method includes: stacking a polymer nonwoven fabric holding or containing piezoelectric ceramic particles and a polymer resin sheet containing piezoelectric ceramic particles such that at least one layer of the polymer nonwoven fabric is included; and integrating the stacked structure by compression-bonding using a press. The polymer nonwoven fabric holding or containing the piezoelectric ceramic particles is a polymer nonwoven fabric produced by an electrospinning method in which slurry obtained by dispersing the piezoelectric ceramic particles in a solution of a polymer in water or an organic solvent is subjected to electrospinning.

### Effects of the Invention

In the piezoelectric device of the present invention, since a polymer resin sheet layer and a polymer nonwoven fabric layer are stacked and integrated, high piezoelectric properties can be exhibited without impairing flexibility. Since the polymer resin sheet is highly filled with piezoelectric ceramic particles in the amount of 50% by volume to 80% by volume, electric charge is induced at the piezoelectric device surface so that electric charge can easily be extracted. Furthermore, since the polymer nonwoven fabric layer is highly filled with piezoelectric ceramic particles in the amount of 30% by volume to 60% by volume, high piezoelectric properties can be exhibited without impairing flexibility.

The piezoelectric device of the present invention is a multilayer structure that can provide an electric power output equal to or greater than the electric power output produced by a multilayer structure in which a polymer resin sheet is stacked on each of two main surface sides of a polymer nonwoven fabric layer. Therefore, the power-generation performance can be further improved and retained.

### BRIEF DESCRIPTION OF THE DRAWINGS

FIG. 1 is a diagram illustrating an exemplary section of a piezoelectric device.

FIG. 2 is a diagram illustrating an exemplary polarization process for a multilayer structure.

FIG. 3 is a diagram illustrating a piezoelectric device under test.

FIG. 4 is a circuit diagram illustrating a method of measuring electric power produced by the piezoelectric effect.

FIG. 5 is a diagram illustrating the electric power output measurement result.

### MODE FOR CARRYING OUT THE INVENTION

The inventors have researched the electric power output of a piezoelectric device formed by stacking and integrating polymer nonwoven fabric layers and polymer resin sheet layers and have found a phenomenon in which as the number of polymer nonwoven fabric layers in the multilayer structure increases, the electric power output increases, and conversely as the number of layers further increases, the electric power output decreases. In other words, it has been found that the number of polymer nonwoven fabric layers and polymer resin sheet layers has an optimum value for the electric power output. The present invention is based on such findings.

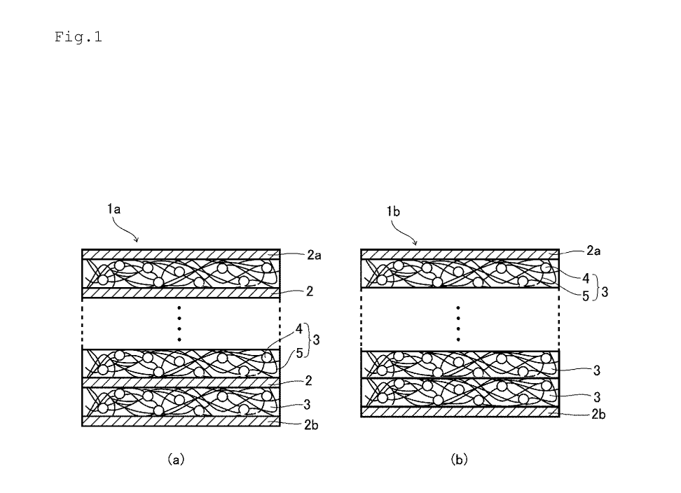

FIG. 1 illustrates an exemplary section of a piezoelectric device in the present invention. In FIG. 1, two main surface sides on the front and the back of a multilayer structure are both polymer resin sheets. FIG. 1(a) illustrates an example in which polymer resin sheets and polymer nonwoven fabrics are alternately stacked, and FIG. 1(b) illustrates an example in which a plurality of polymer nonwoven fabric layers are stacked. FIG. 1 is a schematic diagram illustrating a multilayer structure with a thickness magnified, in which piezoelectric ceramic particles, nonwoven fabrics, and the like are illustrated conceptually.

In FIG. 1(a), a polymer resin sheet 2 containing piezoelectric ceramic particles and a polymer nonwoven fabric 3 holding or containing piezoelectric ceramic particles 4 in a nonwoven fabric 5 are alternately stacked, and polymer resin sheets 2a and 2b form the front and the back of a multilayer structure 1a. When the number of layers of polymer resin sheets 2 is n and the number of layers of polymer nonwoven fabrics 3 is m, the relation of the numbers of layers in the multilayer structure 1a is written as n=m+1. In a minimum structure of the multilayer structure, n is two and m is one to serve as a minimum structure of the multilayer structure.

In FIG. 1(b), a plurality of polymer nonwoven fabrics 3 described above are stacked, and polymer resin sheets 2a and 2b form the front and the back of a multilayer structure 1b. Also in this case, in a minimum multilayer structure, n is two and m is one. In the relational expression of the number of layers in the multilayer structure 1b, n is fixed at 2, and m is a value such as 2, 3, 4, . . . depending on the number of layers of polymer nonwoven fabrics 3.

The multilayer structure 1 is not limited to the multilayer structures illustrated in FIGS. 1(a) and 1(b) and may be any multilayer structure including at least one layer of a polymer nonwoven fabric 3. For example, a plurality of layers of polymer nonwoven fabrics 3 may be stacked, and this multilayer structure and the polymer resin sheet 2 may be stacked.

The electric power output of the piezoelectric device including the multilayer structure 1 was examined. As piezoelectric devices, as illustrated in FIG. 1(a), a multilayer structure 1a was prepared in which polymer resin sheets 2 and polymer nonwoven fabrics 3 are alternately stacked and polymer resin sheets 2a and 2b form the front and the back of the multilayer structure, and as illustrated in FIG. 1(b), a multilayer structure 1b was also prepared in which a plurality of layers of polymer nonwoven fabrics 3 are stacked and polymer resin sheets 2a and 2b form the front and the back of the multilayer structure.

As polymer resin sheets 2, sheets containing 50% by volume of NKN particles with the average particle size of 1 μm in a PVA resin were prepared, each sheet having a thickness of 40 μm.

Polymer nonwoven fabrics 3 are nonwoven fabrics having a thickness of 40 μm produced by an electrospinning method using PVDF slurry containing 50% by volume of NKN particles with the average particle size of 1 μm. The average diameters of fibers of the polymer nonwoven fabric 3 were prepared according to three standards: 0.05 μm, 0.5 μm, and 5 μm.

The multilayer structure 1a is represented by an n-m structure, where n is the number of layers of polymer resin sheets 2 and m is the number of layers of polymer nonwoven fabrics 3. As samples tested for measuring the electric power output of piezoelectric devices, six multilayer structures: 2-1 structure, 3-2 structure, 4-3 structure, 5-4 structure, 6-5 structure, and 7-6 structure were prepared, and for each multilayer structure, samples were prepared according to three standards with different average diameters of fibers: 0.05 μm, 0.5 μm, and 5 μm. In total, 18 samples were prepared.

The multilayer structure 1b has two layers of polymer resin sheets 2 that form the front and the back of the multilayer structure and therefore is represented by a 2-m structure, where m is the number of layers of polymer nonwoven fabrics 3. As samples tested for measuring the electric power output of the piezoelectric devices, five multilayer structures: 2-1 structure, 2-3 structure, 2-5 structure, 2-7 structure, and 2-9 structure were prepared, and for each multilayer structure, samples were prepared according to three standards with different average diameters of fibers: 0.05 μm, 0.5 μm, and 5 μm. In total, 15 samples were prepared.

Each of the multilayer structure 1a and the multilayer structure 1b was cut into a size of 13 mm×28 mm and pressed under a pressure of 40 MPa and a temperature of 65° C. for 3 minutes to form a sheet-like multilayer structure.

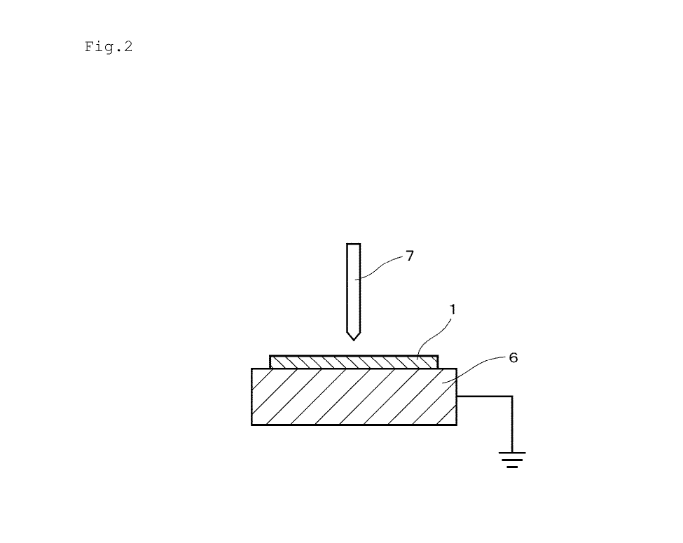

FIG. 2 is a diagram illustrating an exemplary polarization process for the multilayer structure 1a and the multilayer structure 1b. The multilayer structure 1 was placed on a grounded sample stage 6, and polarization was conducted by corona discharge generated by applying a direct-current electric field with a needle electrode 7 disposed 3 mm away from the upper surface of the multilayer structure 1 in the vertical direction to produce a piezoelectric device. The process conditions are at room temperature, at a voltage of 20 kV, and for a process time of 10 minutes.

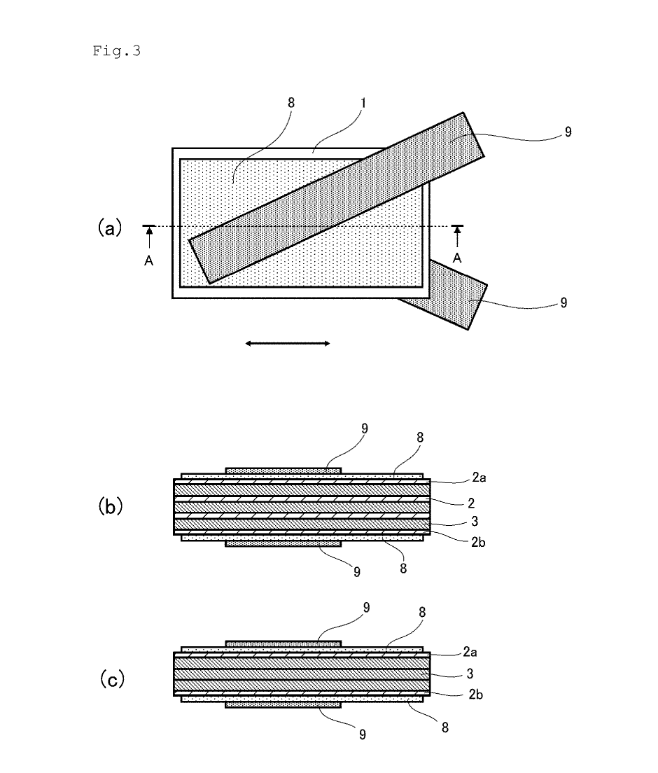

FIG. 3 is a diagram of a piezoelectric device under test. The layer thickness is magnified. FIG. 3(a) is a plan view, FIG. 3(b) illustrates an A-A section of a piezoelectric device A obtained from the multilayer structure 1a illustrated in FIG. 1, and FIG. 3(c) illustrates an A-A section of a piezoelectric device B obtained from the multilayer structure 1b illustrated in FIG. 1. A silver paste 8 was applied on both surfaces of the piezoelectric devices A and B including the multilayer structure 1 subjected to polarization to form upper and lower electrodes, to which copper foil tapes 9 were attached. Piezoelectric devices under test were thus prepared.

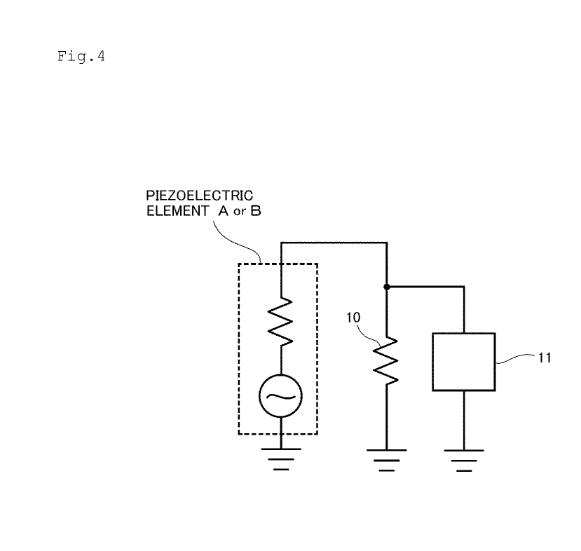

FIG. 4 is a circuit diagram illustrating a method of measuring electric power generated by the piezoelectric effect. Using the circuit illustrated in FIG. 4, the electric power output per vibration was measured by applying stretching vibration at 170 Hz in the longitudinal direction of the piezoelectric devices A and B (the direction of the arrow illustrated in FIG. 3). The piezoelectric devices A and B were each connected to a load resistance 10, and the electric power produced in the load resistance 10 was measured by an oscilloscope 11.

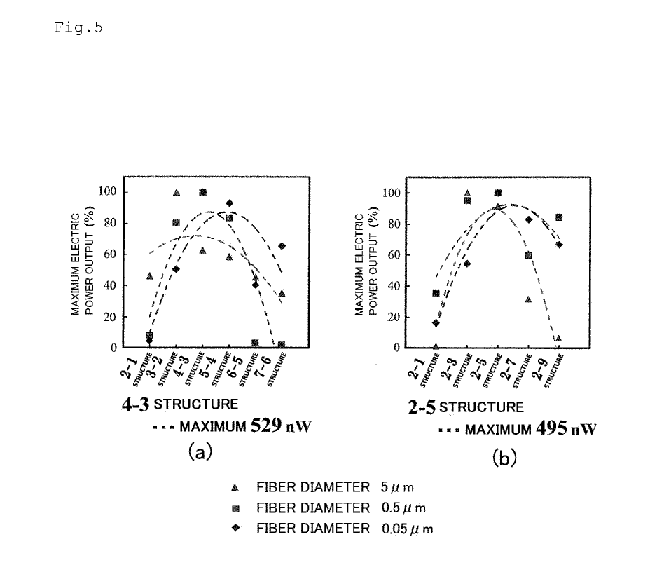

The measurement result is illustrated in FIG. 5. FIG. 5(a) illustrates the result for the piezoelectric device A obtained from the multilayer structure 1a, and FIG. 5(b) illustrates the result for the piezoelectric device B obtained from the multilayer structure 1b. The electric power output is expressed in percentage relative to the maximum electric power output, where the maximum electric power output is 100%. The maximum electric power output of the piezoelectric device A was obtained from the 4-3 structure when the average diameters of fibers (fiber diameter) were 0.05 μm and 0.5 μm, and the electric power output was 529 nW. The maximum electric power output of the piezoelectric device B was obtained from the 2-5 structure when the average diameters of fibers (fiber diameter) were 0.05 μm and 0.5 μm, and the electric power output was 495 nW.

The tensile stress and the strain in a tensile test were larger in the piezoelectric device A than in the piezoelectric device B. Based on this result, the piezoelectric device A is a preferable structure.

As illustrated in FIG. 5, the multilayer structures 1a and 1b with 2-1 structure in which two polymer resin sheets 2 are stacked one by one on two main surface sides of a sheet of a polymer nonwoven fabric 3 serve as a minimum unit of the multilayer structure 1. The electric power output tends to increase as the number of layers of polymer nonwoven fabrics 3 increases from this minimum unit. However, the electric power output does not monotonously increase, and the electric power output is largest with 4-3 structure in the case of the piezoelectric device A and with 2-5 structure in the case of the piezoelectric device B. After that, the electric power output tends to decrease as the number of layers of polymer nonwoven fabrics 3 increases. In other words, the number of layers of polymer resin sheets 2 and polymer nonwoven fabrics 3 has the optimum value for the electric power output.

The present invention specifies a certain range of optimum values on both sides and provides a multilayer structure that achieves an electric power output equal to or greater than the electric power output produced by the multilayer structure 1 of the above-noted minimum unit. Specifically, in the case of the piezoelectric device A, 2-1 structure, 3-2 structure, 4-3 structure, 5-4 structure, 6-5 structure, and 7-6 structure, preferably 2-1 structure, 3-2 structure, 4-3 structure, 5-4 structure, and 6-5 structure, and more preferably 3-2 structure, 4-3 structure, and 5-4 structure are provided. In the case of the piezoelectric device B, 2-1 structure, 2-3 structure, 2-5 structure, 2-7 structure, and 2-9 structure, and preferably 2-1 structure, 2-3 structure, 2-5 structure, and 2-7 structure are provided.

The piezoelectric ceramic particles contained in the polymer resin sheet or the piezoelectric ceramic particles held or contained in the polymer nonwoven fabric may be piezoelectric ceramic particles of the same kind or may be piezoelectric ceramic particles of different kinds. Similarly, the piezoelectric ceramic particles may be piezoelectric ceramic particles of the same kind or may be piezoelectric ceramic particles of different kinds between the polymer resin sheets or between the polymer nonwoven fabrics. It is preferable that piezoelectric ceramic particles having the same composition are used throughout the entire multilayer structure that forms a piezoelectric device.

It is preferable that the piezoelectric ceramic particles are piezoelectric ceramic particles having the perovskite crystal structure. Examples include piezoelectric ceramic particles including one or more of the following elements: niobium, lead, titanium, zinc, barium, bismuth, zirconium, lanthanum, potassium, sodium, calcium, and magnesium. Among these, lead-free NKN particles or barium titanate particles are preferable in terms of high safety to human bodies and environment. NKN particles are ceramics particles represented by (Na_{0.5}K_{0.5})NbO₃. NKN particles can be manufactured by a solid state reaction of sodium carbonate, potassium carbonate, and niobium oxide.

The average particle size of the piezoelectric ceramic particles is 0.1 μm to 10 μm, preferably 0.5 μm to 5 μm, and more preferably 1 μm to 2 μm. If smaller than 0.1 μm, uniform dispersion into a polymer resin sheet or a polymer resin nonwoven fabric is difficult. If exceeding 10 μm, the mechanical strength of the polymer resin sheet or the polymer nonwoven fabric decreases. The average particle size in the present invention is the 50% particle size distribution (D50) measured and calculated by a laser diffraction method.

When piezoelectric ceramic particles are contained in a polymer resin sheet, it is preferable that piezoelectric ceramic particles are bonded using a polymer binder to form a granulated powder. The polymer binder is preferably a material different from the polymer material forming the polymer resin sheet. Specific examples of the polymer binder include acrylic, cellulose-based, PVA-based, polyvinyl acetal-based, urethane-based, and vinyl acetate-based polymers. The use of granulated powder enables high filling of piezoelectric ceramic particles. The granulation is not limited to particular methods, and known methods such as spray granulation, rolling granulation, extrusion granulation, and compression granulation can be used. The average particle size of the granulated powder is 10 μm to 100 μm, and preferably 30 μm to 50 μm.

The polymer material forming the polymer resin sheet is not limited to particular kinds and may be any of thermoplastic resin, thermosetting resin, thermoplastic elastomer, synthetic rubber, and natural rubber. To increase the heat resistance of the piezoelectric device, a crystalline resin having a melting point of 150° C. or higher or an amorphous resin having a glass transition point of 150° C. or higher is more preferable. Specifically, examples include polymer materials such as PVA, polyvinyl butyral (hereinafter referred to as PVB), polystyrene, polyimide, polyamide-imide, polyetherimide, polysulfone, polyphenylsulfone, polyethersulfone, polyarylate, and polyphenyleneether.

The piezoelectric ceramic particles above are contained in the polymer material above. The polymer resin sheet preferably contains an inorganic filler not having piezoelectric properties in addition to the piezoelectric ceramic particles above. When an inorganic filler is contained, it is preferable to mix a conductive filler for the purpose of facilitating charge transfer in the sheet layer. Examples of the conductive filler include graphite, carbon black, carbon nanotubes, fullerene, metal powder, carbon fibers, and metal fibers. As an inorganic filler, a reinforcing material may be contained in order to increase the mechanical strength of the sheet layer. Examples of the reinforcing material include carbon nanotubes, whisker, carbon fibers, and glass fibers.

It is preferable that the polymer resin sheet includes 50% by volume to 80% by volume of piezoelectric ceramic particles and the remainder is the above polymer material above or the remainder is a polymer material and the above inorganic filler not having piezoelectric properties. More preferably, the amount of piezoelectric ceramic particles contained is 70% by volume to 80% by volume. When the polymer resin sheet is highly filled with piezoelectric ceramic particles, electric charge is easily induced at the surface of the polymer resin sheet layer. The polymer resin sheet preferably contains at least 20% by volume of the above polymer material. If the amount of piezoelectric ceramic particles is smaller than 50% by volume, the piezoelectric properties are not improved, and if exceeding 80% by volume, the mechanical strength of the polymer resin sheet decreases. In calculation of the content ratio, piezoelectric ceramic particles refer to particles before being formed into the granulated powder.

The polymer resin sheet can be produced by any method that can form a thin sheet. In the present invention, a preferred production method includes dispersing a filler such as the above piezoelectric ceramic particles in water or an organic solvent having the polymer material dissolved to produce slurry, applying this slurry on a support material to form a thin film, and removing water or the organic solvent by, for example, drying. The slurry can be applied on a support material by known methods such as tape casting represented by doctor blading, and spin coating.

The thickness of one polymer resin sheet is 10 μm to 100 μm, and preferably 30 μm to 50 μm. If the thickness of the polymer resin sheet layer is smaller than 10 μm, the mechanical strength of the resultant piezoelectric device decreases, and if exceeding 100 μm, the flexibility decreases to possibly cause cracks when vibration is applied to the piezoelectric device.

The polymer nonwoven fabric may be any fabric that is formed by bonding or intertwining a fibered polymer material by a thermal/mechanical or chemical action. The average diameter of fibers forming the polymer nonwoven fabric is preferably 0.05 μm to 5 μm, and more preferably 0.5 μm to 1 μm. If the average diameter is greater than 5 μm, the porous volume of the nonwoven fabric layer decreases and therefore the power-generation performance decreases. If the average diameter is smaller than 0.05 μm, the stress applied to the piezoelectric ceramic particles by the fibers is smaller and the power-generation performance decreases. The average diameter of the fibers in the present invention is the average value measured and calculated from an image obtained by a scanning electron microscope.

The polymer material to form the polymer nonwoven fabric is not limited to particular kinds, and whether it has the piezoelectric properties resulting from the molecular structure does not matter. In terms of heat resistance, a crystalline resin having a melting point of 150° C. or higher or an amorphous resin having a glass transition point of 150° C. or higher is preferable, and those with high flexibility are more preferable. Specifically, examples include PVA, PVB, PVDF, a tetrafluoroethylene-ethylene copolymer, a tetrafluoroethylene-hexafluoropropylene copolymer, and a tetrafluoroethylene-perfluoroalkoxyethylene copolymer.

The piezoelectric ceramic particles described above are held or contained in the polymer nonwoven fabric. It is preferable that the polymer nonwoven fabric holds or contains an inorganic filler not having the piezoelectric properties, in addition to the above piezoelectric ceramic particles. As the inorganic filler, a conductive filler is preferably held or contained in order to facilitate charge transfer in the nonwoven fabric layer. Examples of the conductive filler include graphite, carbon black, carbon nanotubes, fullerene, and metal powder. As the inorganic filler, a reinforcing material can be held or contained in order to increase the mechanical strength of the nonwoven fabric layer. Examples of the reinforcing material include carbon nanotubes and whisker. As used herein “held” means that piezoelectric ceramic particles are fixed between fibers of the polymer nonwoven fabric, and “contained” means that piezoelectric ceramic particles are included in the inside of the fibered polymer material.

It is preferable that the polymer nonwoven fabric holds or contains 30% by volume to 60% by volume of piezoelectric ceramic particles and the remainder is the fibered polymer material or the remainder is the fibered polymer material and the inorganic filler not having the piezoelectric properties. More preferably, 50% by volume to 60% by volume of the piezoelectric ceramic particles are held or contained. It is preferable that at least 40% by volume of the fibered polymer material is contained. If the amount of piezoelectric ceramic particles is smaller than 30% by volume, the piezoelectric properties are not improved, and if exceeding 60% by volume, the mechanical strength of the polymer nonwoven fabric decreases.

The polymer nonwoven fabric can be produced by any method that can form a thin nonwoven fabric using fibers with the average diameter of 0.05 μm to 5 μm. In the present invention, the polymer nonwoven fabric is preferably produced by an electrospinning method using slurry obtained by dispersing the piezoelectric ceramic particles in a solution of a polymer material dissolved in water or an organic solvent. The electrospinning method is a process of producing a nonwoven fabric by applying voltage between the needle of the syringe and the collector of an electrospinning apparatus and ejecting slurry in the syringe toward the collector. The shape of the collector may be, for example, but not limited to, a drum shape, a disc shape, or a plate shape. A drum-shaped collector that can produce a large-area nonwoven fabric is preferred. The resultant nonwoven fabric may be dried to remove water or an organic solvent.

The thickness of a sheet of the polymer nonwoven fabric is 10 μm to 300 μm, and preferably 120 μm to 200 μm. If the thickness of the polymer nonwoven fabric is smaller than 10 μm, the piezoelectric properties of the resultant piezoelectric device decrease, and if exceeding 300 μm, breakage may occur in the inside of the polymer nonwoven fabric when vibration is applied to the piezoelectric device.

In the piezoelectric device of the present invention, the multilayer structure of polymer resin sheets and polymer nonwoven fabrics is integrated to obtain a sheet-like piezoelectric device. An example of the integration process is compression bonding using a press.

The polarization process for the piezoelectric device of the present invention preferably includes the step of applying a direct-current electric field to the integrated piezoelectric device. Specific examples of the polarization process include a process using corona discharge in the atmospheric air and a process of applying a direct-current electric field in silicone oil heated to 100° C. to 200° C.

In the piezoelectric device of the present invention, polymer resin sheet layers and nonwoven fabric layers are integrated, and the polymer resin sheet layer is highly filled with piezoelectric ceramic particles, whereby electric charge is easily induced at the piezoelectric device surface and electric charge can easily be extracted. The nonwoven fabric layer highly filled with piezoelectric ceramic particles can exhibit high piezoelectric properties without impairing flexibility. In addition, the power-generation performance can be improved by optimizing the thickness of the sheet layer, the thickness of the nonwoven fabric layer, and the number of sheet layers and nonwoven fabric layers. The piezoelectric device of the present invention therefore can be applied to the applications including vibration energy harvesting, current sensors, and voltage sensors, particularly suitable for vibration energy harvesting using ambient vibration.

### EXAMPLES

### Examples 1 to 14 and Comparative Examples 1 to 7

NKN particles used as piezoelectric ceramics were prepared as follows. Na₂CO₃ (purity 99.9%), K₂CO₃ (purity 99.9%), and Nb₂O₅ (purity 99.9%) were used as raw material powders. The raw material powders were mixed well, and the mixture was sintered at 1,098° C. for two hours and then crushed to produce powder with the average particle size of 1 μm. This powder was dispersed in a polyurethane solution serving as a polymer binder, and granulated powder was produced by spray drying.

The polymer resin sheet was produced by dispersing the granulated powder in an aqueous solution of 7% by mass of PVA to prepare slurry and tape-casting the slurry on a support material. In tape casting, a doctor blade-type coater (IMC-70F0-C manufactured by IMOTO MACHINERY CO., LTD.) was used. The resultant sheet was dried at room temperature to remove water, resulting in a polymer resin sheet.

The polymer nonwoven fabric was produced by electrospinning slurry obtained by dispersing the NKN particles in a dimethyl sulfoxide solution having PVDF dissolved. IMC-1639 manufactured by IMOTO MACHINERY CO., LTD. was used as an electrospinning apparatus. The concentration of the dimethyl sulfoxide solution having PVDF dissolved was 0.11 g/mL, and slurry obtained by dispersing 50% by volume of NKN particles with respect to PVDF was used. Voltage of 18 kV was applied between the needle of the syringe and the collector to eject the slurry in the syringe toward the collector to produce nonwoven fabric. The resultant nonwoven fabric was dried at room temperature to remove dimethyl sulfoxide, resulting in a polymer nonwoven fabric.

The polymer resin sheet and the polymer nonwoven fabric were cut each into a size of 13 mm×28 mm and alternately stacked or a plurality of polymer nonwoven fabrics were stacked, and then pressed by a press at a pressure of 40 MPa and a temperature of 65° C. for three minutes to obtain a multilayer structure. The structure and thickness of the multilayer structure, the amount of NKN held or contained in the polymer resin sheet and the polymer nonwoven fabric, the thickness of the polymer resin sheet and the polymer nonwoven fabric, and the average diameter of fibers forming the polymer nonwoven fabric are listed in Table 1 and Table 2.

As illustrated in FIG. 3, a piezoelectric device was obtained by applying silver paste 8 on both of the front and back surfaces of the resultant multilayer structure to form upper and lower electrodes and attaching copper foil tapes 9. To this piezoelectric device, stretching vibration of 170 Hz was applied in the longitudinal direction (the direction of the arrow illustrated in FIG. 3) of the piezoelectric device using a circuit illustrated in FIG. 4, and the electric power output per vibration was measured. The result is listed in Table 1 and Table 2.

TABLE 1

| | Example | | | | | | | |
|---|---|---|---|---|---|---|---|---|
| | 1 | 2 | 3 | 4 | 5 | 6 | 7 | 8 |
| Sheet structure, | 2-1 | 3-2 | 4-3 | 4-3 | 4-3 | 4-3 | 4-3 | 5-4 |
| sheet layer-nonwoven | | | | | | | | |
| fabric layer | | | | | | | | |
| Thickness of sheet | 40 | 40 | 40 | 40 | 40 | 40 | 100 | 40 |
| layer, μm | | | | | | | | |
| Amount of NKN | 70 | 70 | 70 | 70 | 70 | 80 | 80 | 70 |
| contained in sheet | | | | | | | | |
| layer, % by volume | | | | | | | | |
| Thickness of nonwoven | 40 | 40 | 40 | 40 | 40 | 40 | 40 | 40 |
| fabric layer, μm | | | | | | | | |
| Average diameter of | 0.5 | 0.5 | 0.05 | 0.5 | 5 | 0.5 | 0.5 | 0.5 |
| fibers of nonwoven | | | | | | | | |
| fabric layer, μm | | | | | | | | |
| Electric power output | 257 | 531 | 505 | 664 | 399 | 830 | 601 | 589 |
| (per vibration), nW | | | | | | | | |

| | Example | Comparative Example | | | | | |
|---|---|---|---|---|---|---|---|
| | 9 | 1 | 2 | 3 | 4 | 5 | 6 |
| Sheet structure, | 6-5 | 7-6 | 4-3 | 4-3 | 4-3 | 4-3 | 4-3 |
| sheet layer- | | | | | | | |
| nonwoven fabric | | | | | | | |
| layer | | | | | | | |
| Thickness of sheet | 40 | 40 | 40 | 40 | 5 | 40 | 40 |
| layer, μm | | | | | | | |
| Amount of NKN | 70 | 70 | 30 | 90 | 70 | 70 | 70 |
| contained in sheet | | | | | | | |
| layer, % by volume | | | | | | | |
| Thickness of | 40 | 40 | 40 | 40 | 40 | 40 | 40 |
| nonwoven fabric | | | | | | | |
| layer, μm | | | | | | | |
| Average diameter | 0.5 | 0.5 | 0.5 | 0.5 | 0.5 | 0.02 | 10 |
| of fibers of | | | | | | | |
| nonwoven fabric | | | | | | | |
| layer, μm | | | | | | | |
| Electric power | 274 | 75 | 149 | *Note | *Note | 109 | 161 |
| output (per | | | | | | | |
| vibration), nW | | | | | | | |

*Note: unable to be measured because of breakage of the sheet layer

TABLE 2

| | | | | | | Comparative |
|---|---|---|---|---|---|---|
| | Example | | | | | Example |
| | 10 | 11 | 12 | 13 | 14 | 7 |
| Sheet structure, sheet | 2-1 | 2-1 | 2-1 | 2-1 | 2-1 | 2-1 |
| layer-nonwoven fabric | | | | | | |
| layer | | | | | | |
| Thickness of sheet | 40 | 40 | 40 | 40 | 40 | 40 |
| layer, μm | | | | | | |
| Amount of NKN | 70 | 70 | 70 | 70 | 70 | 70 |
| contained in sheet | | | | | | |
| layer, % by volume | | | | | | |
| Thickness | 15 | 40 | 120 | 200 | 280 | 360 |
| of nonwoven | | | | | | |
| fabric layer, μm | | | | | | |
| Average diameter of | 0.5 | 0.5 | 0.5 | 0.5 | 0.5 | 0.5 |
| fibers of nonwoven | | | | | | |
| fabric layer, μm | | | | | | |
| Electric power output | 273 | 553 | 719 | 790 | 403 | 63 |
| (per vibration), nW | | | | | | |

As indicated by Example 6, the piezoelectric device with 4-3 structure as a multilayer structure provides the largest electric power output. The electric power output is larger as the amount of NKN particles contained in the polymer resin sheet layer is larger. However, in Comparative Example 3 (the thickness of a layer of the polymer resin sheet: 40 μm, the amount of NKN particles contained: 90% by volume) and in Comparative Example 4 (the thickness of a layer of the polymer resin sheet: 5 μm, the amount of NKN particles contained: 70% by volume), the sheet layer broken and the electric power output was unable to be measured. The electric power output exhibited a satisfactory value when the average diameter of fibers of the polymer nonwoven fabric layer was in a range of 0.05 μm to 5 μm. Table 2 lists the electric power output depending on the thickness of the polymer nonwoven fabric layer. Example 13 (the thickness of a polymer nonwoven fabric layer is 200 μm) achieves the most excellent result.

### INDUSTRIAL APPLICABILITY

The present invention can be used in the field of vibration energy harvesting using ambient vibration.

### REFERENCE SIGNS LIST

1 multilayer structure
2 polymer resin sheet
3 polymer nonwoven fabric
4 piezoelectric ceramic particles
5 nonwoven fabric
6 sample stage
7 needle electrode
8 silver paste
9 copper foil tape
10 load resistance
11 oscilloscope

1. A piezoelectric device comprising a multilayer structure in which a polymer nonwoven fabric holding or containing piezoelectric ceramic particles and a polymer resin sheet containing piezoelectric ceramic particles are stacked such that at least one layer of the polymer nonwoven fabric is included, wherein
the multilayer structure is a multilayer structure that is able to provide an electric power output equal to or larger than an electric power output produced by a multilayer structure in which a layer of the polymer resin sheet is stacked on each of two main surface sides of a layer of the polymer nonwoven fabric.

2. The piezoelectric device according to claim 1, wherein
the polymer nonwoven fabric is a nonwoven fabric with a thickness per layer of 10 μm to 300 μm in which an average diameter of fibers forming the polymer nonwoven fabric is 0.05 μm to 5 μm and 30% by volume to 60% by volume of piezoelectric ceramic particles are held or contained, and
the polymer resin sheet is a sheet with a thickness per layer of 10 μm to 100 μm in which 50% by volume to 80% by volume of piezoelectric ceramic particles are contained.

3. The piezoelectric device according to claim 1, wherein in the multilayer structure, a plurality of the polymer nonwoven fabrics are stacked.

4. The piezoelectric device according to claim 3, wherein each of two main surface sides of the multilayer structure is the polymer resin sheet.

5. The piezoelectric device according to claim 1, wherein in the multilayer structure, the polymer nonwoven fabric and the polymer resin sheet are alternately stacked.

6. The piezoelectric device according to claim 5, wherein each of two main surface sides of the multilayer structure is the polymer resin sheet.

7. A method of manufacturing a piezoelectric device as claimed in claim 1, the method comprising:
stacking a polymer nonwoven fabric holding or containing piezoelectric ceramic particles and a polymer resin sheet containing piezoelectric ceramic particles to form a multilayer structure such that at least one layer of the polymer nonwoven fabric is included; and
integrating the multilayer structure by compression-bonding using a press, wherein
the polymer nonwoven fabric holding or containing the piezoelectric ceramic particles is a polymer nonwoven fabric produced by an electrospinning method in which slurry obtained by dispersing the piezoelectric ceramic particles in a solution of a polymer in water or an organic solvent is subjected to electrospinning.
